(19) United States
(12) Patent Application Publication
(10) Pub. No.: US 2025/0277810 A1
(43) Pub. Date: Sep. 4, 2025

(54) TESTING APPARATUS AND ITS CONDUCTIVE TERMINAL

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Chih-Chieh LIAO, HSINCHU CITY (TW); Yu-Min SUN, HSINCHU CITY (TW); Chih-Feng CHENG, HSINCHU CITY (TW)

(21) Appl. No.: 18/945,457

(22) Filed: Nov. 12, 2024

(30) Foreign Application Priority Data
Mar. 1, 2024 (TW) 113107566

(51) Int. Cl. G01R 1/04

(52) U.S. Cl. CPC G01R 1/0416

(57) ABSTRACT

A testing apparatus includes a circuit board, a base and a conductive terminal. The circuit board includes a board body, a via portion penetrated through the board body, and an electrical contact located on one surface of the board body and electrically connected to the via portion. The base is located on the circuit board and formed with a limiting groove. The conductive terminal includes a main body held within the limiting groove, an abutment portion extended outwardly from one side of the main body, a conductive portion extended outwardly from the side of the main body and removably contacting with the electrical contact, an elastic piece portion connected to the conductive portion and the abutment portion, and a supporting portion extended outwardly from another side of the main body, arranged opposite to the conductive portion, and removably contacting with the circuit board.

### RELATED APPLICATIONS

This application claims priority to Taiwan Application Serial Number 113107566, filed Mar. 1, 2024, the disclosures of which are incorporated herein by reference in their entireties.

### BACKGROUND

### Field of Invention

The present disclosure relates to a testing apparatus. More particularly, the present disclosure relates to a testing apparatus of an electronic component and a conductive terminal of the testing apparatus.

### Description of Related Art

In general, a test operator tests electronic component s through a testing apparatus. The electronic component s are for example, Quad Flat Package (QFP), Low Profile Quad Flat Package (LQFP), Analog to Digital converter (ADC), and digital analog Converter (DAC), etc.

However, the contact pins of the testing apparatus will cause excessive voltage drop (IR drop) due to their original structural design, which will not only affect the test results of electronic components, but also shorten the service life of contacts on a circuit board of the testing apparatus.

Therefore, the above-mentioned technologies obviously still have inconveniences and defects, which are issues that the industry needs to solve urgently.

### SUMMARY

One aspect of the present disclosure is to provide a testing apparatus and its conductive terminal for solving the difficulties mentioned above in the prior art.

In one embodiment of the present disclosure, a testing apparatus includes a circuit board, at least one base and at least one conductive terminal. The circuit board includes a board body, at least one via portion penetrated through the board body, and at least one electrical contact located on one surface of the board body and electrically connected to the via portion. The base is located on the circuit board and formed with at least one limiting groove. The conductive terminal includes a main body held within the limiting groove, an abutment portion extended outwardly from one side of the main body for contacting with a contact pin of a device under test (DUT), a conductive portion extended outwardly from the side of the main body, and removably contacting with the electrical contact, an elastic piece portion connected to the conductive portion and the abutment portion, and a supporting portion extended outwardly from another side of the main body, arranged opposite to the conductive portion, and removably contacting with the circuit board.

In one embodiment of the present disclosure, a conductive terminal includes a main body, an abutment portion extended outwardly from one side of the main body for contacting with a contact pin of a device under test (DUT), a conductive portion extended outwardly from the side of the main body for contacting an electrical contact of a circuit board, an elastic piece portion connected to the abutment portion and the conductive portion, and at least one supporting portion extended outwardly from another side of the main body, arranged opposite to the conductive portion, and removably contacting with the circuit board.

Thus, through the construction of the embodiments above, the disclosure is able to improve the problem of voltage drop caused by the testing apparatus, thus, not only advance the test results of electronic component s, but also maintain the service life of contacts of the circuit board of the testing apparatus.

The above description is merely used for illustrating the problems to be resolved, the technical methods for resolving the problems and their efficacies, etc. The specific details of the present disclosure will be explained in the embodiments below and related drawings.

The above description is only an overview of the technical solution of the present disclosure. In order to understand the technical means of the present disclosure, and implement the technical means according to the content of the description, and in order to make the above and other objects, features and advantages of the present disclosure more obvious and understandable, preferred embodiments are specifically cited below and described in detail with reference to the accompanying drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is an exploded view of a testing apparatus according to one embodiment of the present disclosure.

FIG. 2 is a cross-sectional view of the testing apparatus in FIG. 1 after assembly.

FIG. 3 is an enlargement view of the first conductive terminal in FIG. 1.

FIG. 4 is an operative schematic view of the testing apparatus in FIG. 2.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

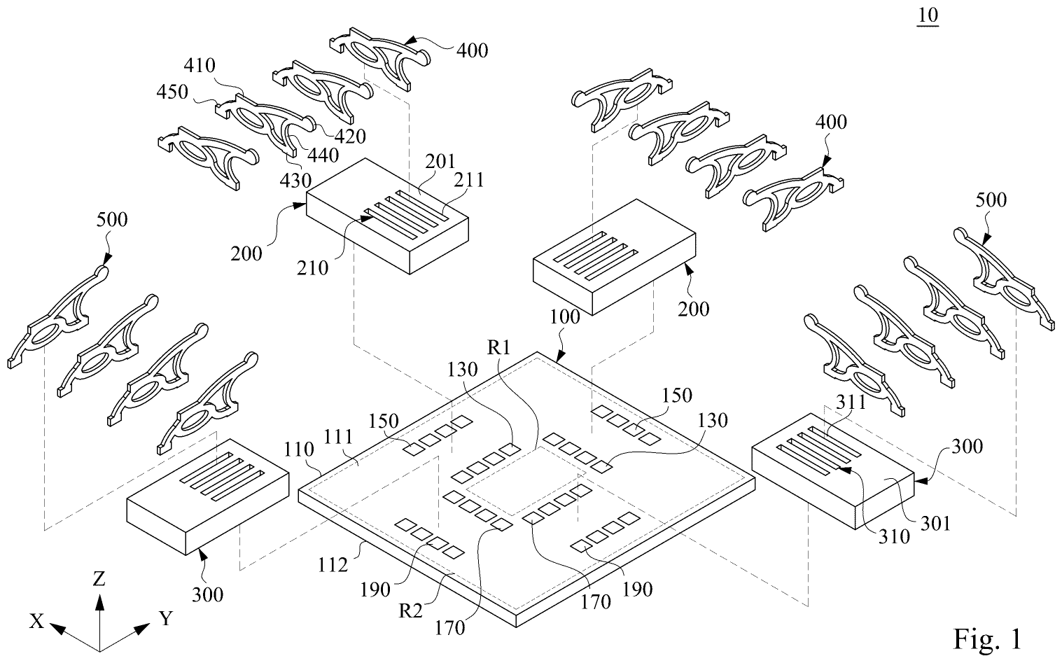

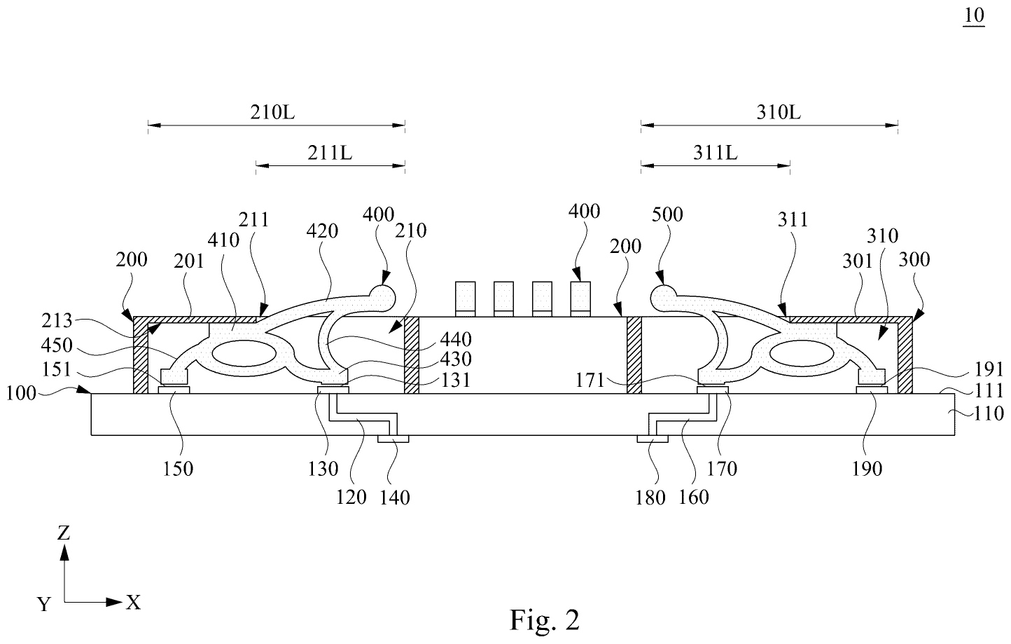

Reference is now made to FIG. 1 to FIG. 2, in which FIG. 1 is an exploded view of a testing apparatus 10 according to one embodiment of the present disclosure. FIG. 2 is a cross-sectional view of the testing apparatus 10 in FIG. 1 after assembly. In this embodiment, the testing apparatus 10 includes a circuit board 100, a plurality (e.g., four) of bases (refer to a first base 200 and a second base 300) and a plurality of conductive terminal groups (e.g., four conductive terminal groups). The circuit board 100 includes a board body 110, a plurality of electrical contacts (e.g., first electrical contacts 130 and second electrical contacts 170 opposite to each other), a plurality of dummy contacts (e.g., first dummy contacts 150 and second dummy contacts 190 opposite to each other), a plurality of rear contacts (e.g., first rear contacts 140 and second rear contacts 180) and a plurality of via portions (e.g., first via portions 120 and second via portions 160). The board body 110 includes a top surface 111 and a rear surface 112 opposite to each other. These electrical contacts are spaced located on the top surface 111 of the board body 110. For example, these electrical contacts (e.g., first electrical contacts 130 and second electrical contacts 170) are spaced located on the top surface 111 of the board body 110 so as to collectively outline a rectangular contour R1 therein. These dummy contacts are spaced located on the top surface 111 of the board body 110, and electrically insulated from the via portions and the electrical contacts. For example, these dummy contacts (e.g., these first dummy contacts 150 and these second dummy contacts 190) are spaced located on the top surface 111 of the board body 110 so as to collectively outline another rectangular contour R2 capable of surrounding these electrical contacts (e.g., first electrical contacts 130 and second electrical contacts 170). These rear contacts (e.g., first rear contacts 140 and second rear contacts 180) are spaced located on the rear surface 112 of the board body 110. The via portions are penetrated through the board body 110, respectively, and each of the via portions (e.g., first via portion 120) is electrically connected to one of the electrical contacts (e.g., first electrical contact 130) and one of the rear contacts (e.g., first rear contacts 140), respectively.

These bases are mounted on the top surface 111 of the board body 110. For example, these first bases 200 and these second bases 300 are opposite to each other. Each of the conductive terminal groups is installed in one of the bases, and each of the conductive terminal groups includes a plurality of conductive terminals (refer to first conductive terminals 400 or second conductive terminals 500). One surface 201 of each of the first bases 200 opposite to the board body 110 is recessed with a plurality of first limiting grooves 210. These first limiting grooves 210 are arranged linearly in sequence. Each of the first conductive terminals 400 is removably held within one of the first limiting grooves 210, and each of the first conductive terminals 400 located within one of the first bases 200 is removably placed against (or at least contacted with) the first electrical contact 130 and the circuit board 100 (e.g., first dummy contact 150), respectively. The opening length 211L of a recess opening 211 of each of the first limiting grooves 210 is smaller than the inner length 210L of the first limiting groove 210. One of the second bases 300 is opposite to one of the first bases 200. One surface 301 of each of the second base 300 opposite to the board body 110 is recessed with a plurality of second limiting grooves 310. These second limiting grooves 310 are arranged linearly in sequence. Each of the second conductive terminals 500 is removably held within one of the second limiting grooves 310, and each of the second conductive terminals 500 located within one of the second bases 300 is removably placed against (or at least contacted with) the second electrical contact 170 and the circuit board 100 (e.g., second dummy contact 190), respectively.

The opening length 311L of a recess opening 311 of each of the second limiting grooves 310 is smaller than the inner length 310L of the second limiting groove 310. The arrangement direction of each of the second limiting grooves 310 (e.g., Y axis) is parallel to the arrangement direction of each of the first limiting grooves 210 (e.g., Y axis).

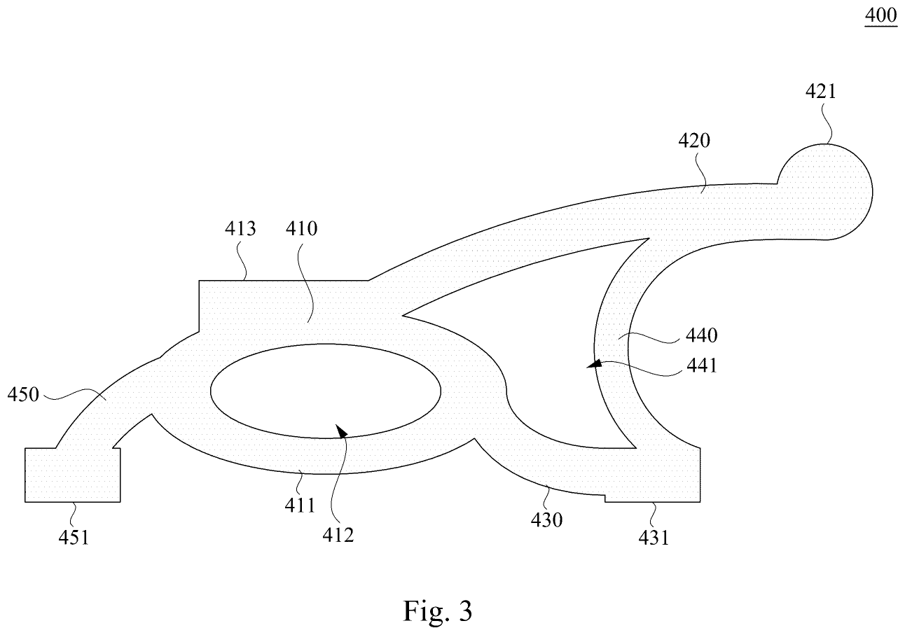

FIG. 3 is an enlargement view of the first conductive terminal 400 in FIG. 1. As shown in FIG. 2 and FIG. 3, in the embodiment, each of the conductive terminals (e.g., first conductive terminal 400) includes a main body 410, an abutment portion 420, a conductive portion 430, an elastic piece portion 440 and a supporting portion 450. The main body 410 is removably held within the first limiting groove 210. The abutment portion 420 is connected to one side of the main body 410, and extended outwards the first limiting groove 210 from the main body 410. The conductive portion 430 is connected to the main body 410, and extended outwardly from the aforementioned side of the main body 410. The conductive portion 430 removably abuts or at least contacts with the first electrical contact 130. The elastic piece portion 440 is resiliently located between the abutment portion 420 and the conductive portion 430, and connected to the abutment portion 420 and the conductive portion 430, respectively. The supporting portion 450 is connected to the main body 410, and extended from another side of the main body 410. The supporting portion 450 is arranged opposite to the conductive portion 430, and removably abutted or at least contacted with the circuit board 100.

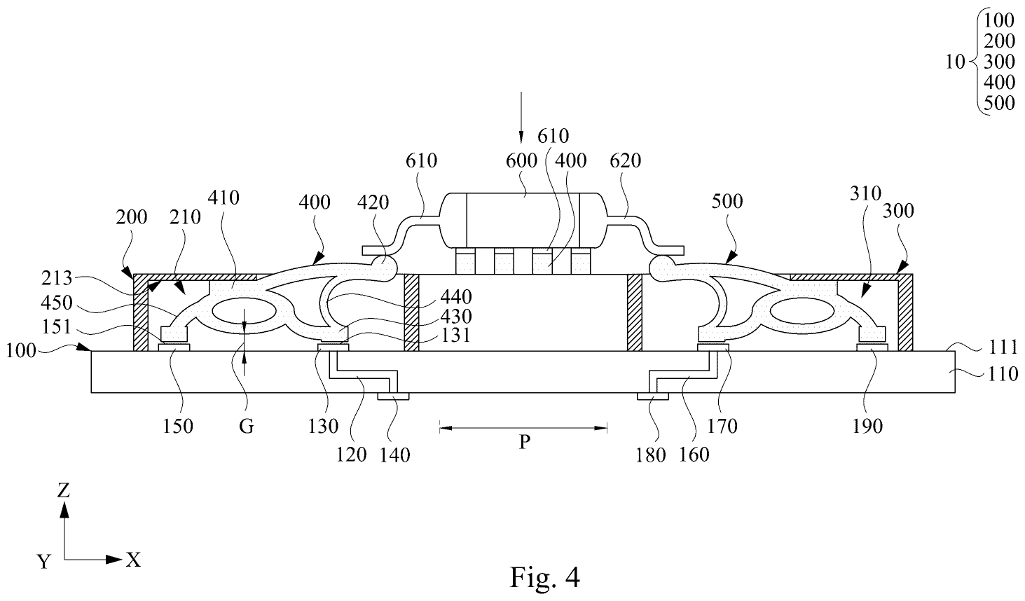

FIG. 4 is an operative schematic view of the testing apparatus 10 in FIG. 2. As shown in FIG. 3 and FIG. 4, when a device under test (called DUT hereinafter, e.g., an electronic component) is placed on the testing apparatus 10, since contact pins (e.g., contact pins 610 and 620) on each side of the DUT 600 are arranged at intervals according to a rectangular contour, the contact pins 610 and 620 of the DUT 600 respectively contact with the first conductive terminals 400 and the second conductive terminals 500 one by one. The abutment portions 420 of each of the first conductive terminals 400 and the second conductive terminals 500 are respectively placed against (or at least contacted with) one of the contact pins 610 and 620 of the DUT 600, so that the DUT 600 and the testing apparatus 10 are electrically connected to each other.

In this way, when the DUT 600 presses down these conductive terminals (e.g., the first conductive terminals 400 and the second conductive terminals 500), since the elastic piece portion 440 of the first conductive terminals 400 can provide a certain amount of elastic deformation, the pressure exerted by the conductive portions 430 of the first conductive terminals 400 on the first electrical contacts 130 can be buffered. Similarly, since the corresponding position of the second conductive terminals 500 can also provide a certain amount of elastic deformation, the pressure exerted by the second conductive terminal 500 on the second electrical contacts 170 can also be buffered. In this way, it not only stabilizes the electrical qualities of the first conductive terminals 400 and the second conductive terminals 500 to the first electrical contacts 130 and second electrical contacts 170, respectively, but also improves the problem of possible voltage drop in the testing apparatus 10. Therefore, the test results of the DUT 600 are improved and the service life of the circuit board 100 contacts of the testing apparatus 10 is maintained.

More specifically, in this embodiment, as shown in FIG. 3 and FIG. 4, the conductive portion 430 of each of the first conductive terminals 400 is a cantilever extending towards the second bases 300 from the main body 410 thereof. The supporting portion 450 of each of the first conductive terminals 400 is a cantilever extending from the main body 410 in a direction away from the abutment portion 420. The abutment portion 420 of each of the first conductive terminals 400 is a cantilever extending laterally toward the second base 300 from the main body 410 thereof. One end of the abutment portion 420 facing away from the main body 410 is provided with an arc-shaped outer edge 421. When the DUT 600 presses the end of the abutment portion 420 facing away from the main body 410, the abutment portion 420 is in contact with the contact pins 610 of the DUT 600 through the arc-shaped outer edge 421, thereby testing residue is not easy to be accumulated on the end of the abutment portion 420.

However, the present disclosure is not limited thereto, in other embodiments, the supporting portion 450 may include two supporting portions 450, and these supporting portions 450 and the conductive portion 430 are arranged in a triangle together.

Furthermore, the main body 410 of each of the first conductive terminals 400 is recessed with a recess 441 connected to the elastic piece portion 440 thereof. The elastic piece portion 440 is convex to protrude into the recess 441 so that a geometric structure formed by the elastic piece portion 440 and the recess 441 can provide a suitable elastic coefficient. Therefore, when the DUT 600 presses down one of the first conductive terminals 400, the recess 441 of the corresponding first conductive terminal 400 allows the elastic piece portion 440 of the corresponding first conductive terminal 400 to continue extending inwards the recess 441, thereby enhancing the elastic deformation of the elastic piece portion 440 and the stability of the first conductive terminal 400. For example, the elastic piece portion 440 is C-shaped or V-shaped, however, the present disclosure is not limited thereto.

Furthermore, as shown in FIG. 2, one surface 151 of the first dummy contact 150 and one surface 131 of the first electrical contact 130 which are connected to the same first conductive terminal 400, are at the same height. In this way, when each of the first conductive terminals 400 is placed on the circuit board 100, the conductive portion 430 of the first conductive terminal 400 is placed against (or at least contacted with) the aforementioned surface 131 of the corresponding first electrical contact 130, and the supporting portion 450 is placed against (or at least contacted with) the aforementioned surface 151 of the corresponding first dummy contact 150. Similarly, one surface 191 of the second dummy contact 190 and one surface 171 of the second electrical contacts 170 which are connected to the same second conductive terminal 500 are at the same height.

Furthermore, for example, the conductive portion 430 of each of the first conductive terminals 400 is a cantilever extending towards the second bases 300 from the main body 410 thereof, the conductive portion 430 is provided with a conductive surface 431 located away from the main body 410 and the elastic piece portion 440. The conductive surface 431 (FIG. 3) is used to be placed against (or at least contact with) the surface 131 of the corresponding first electrical contact 130. The supporting portion 450 is a cantilever extending in the direction away from the abutment portion 420 from the main body 410, one end surface of the supporting portion 450 away from the main body 410 is provided with a supporting surface 451. The supporting surface 451 is used to be placed against (or at least contact with) the surface 151 of the corresponding first dummy contact 150.

Thus, since the aforementioned surface 151 of the first dummy contact 150 is at the same height as the surface 131 of the corresponding first electrical contact 130, the corresponding first conductive terminal 400 can be tested at the same level, so that the first conductive terminals 400 can be more stable test the DUT 600.

Furthermore, since the hardness of one of the first electrical contacts 130, the second electrical contacts 170, the first dummy contacts 150 and the second dummy contacts 190 is greater than the hardness of the board body 110 of the circuit board 100, the supporting portion 450 of the first conductive terminal 400 abuts against the first dummy contact 150 rather than the board body 110 of the circuit board 100. In this way, the supporting portion 450 of each of the first conductive terminals 400 can avoid excessive wear of the board body 110 of the circuit board 100 over a long period of time. In this embodiment, the board body 110 is made of plastic, for example, and the first electrical contacts 130, the second electrical contacts 170, the first dummy contacts 150 and the second dummy contacts 190 are made of metal, for example.

However, the present disclosure is not limited thereto. In other embodiments, the supporting portion 450 of each of the first conductive terminals 400 and each of the second conductive terminals 500 may also be placed against (or at least contact with) the board body 110 of the circuit board 100, rather than the electrical contacts.

In this embodiment, as shown in FIG. 4, comparing to the first dummy contacts 150, the first electrical contact 130 of the circuit board 100 is closer to an orthographic projection P of the DUT 600 onto the board body 110 or the second electrical contact 170 of the circuit board 100, so that signals of the DUT 600 can be sent to the circuit board 100 from the abutment portion 420 via the elastic piece portion 440 and the conductive portion 430 through the minimum resistance and path.

As shown in FIG. 3 and FIG. 4, each of the first conductive terminals 400 is further provided with an elastic ring 411 located between the conductive portion 430 and the supporting portion 450. The elastic ring 411 surrounds to form a through hole 412 therein so that the elastic ring 411 is collectively supported by the conductive portion 430 and the supporting portion 450 in a suspended manner, thereby maintaining a gap G between the elastic ring 411 and the top surface 111 of the board body 110 of the circuit board 100 so as to form a suspension mechanism capable of absorbing vibrations. However, the present disclosure is not limited thereto, the elastic ring 411 may also be in contact with the top surface 111 of the board body 110 in other requirements.

Each of the first conductive terminals 400 is further provided with a pre-press portion 413. The pre-press portion 413 is opposite to the elastic ring 411 (or the board body 110 of the circuit board 100), and arranged between the abutment portion 420 and the supporting portion 450 for abutting against the inner wall 213 of the first base 200 so that the first base 200 exerts a preload pressure on the first conductive terminal 400, thereby pressing the conductive terminal on the board body 110 of the circuit board 100. Therefore, the first conductive terminal 400 can be more stably abutted against the first electrical contact 130 and the first dummy contact 150, thereby more stabilizing the electrical quality of the first conductive terminal 400 to the first electrical contact 130.

In addition, as shown in FIG. 4, when the DUT 600 presses down the first conductive terminal 400 and the second conductive terminal 500, since the first conductive terminal 400 directly abuts against the inner wall 213 of the first base 200 on the one hand, the first conductive terminal 400 directly abuts the first electrical contact 130 and the first dummy contact 150 on the other hand, not only allows the first conductive terminals 400 to stably abut against the first electrical contacts 130 and the first dummy contacts 150, but also prevents the first conductive terminals 400 from generating rolling friction based on the conductive portion 430 as a fulcrum, thereby reducing the wear damages of the first electrical contacts 130.

In the embodiment, the abutment portion 420, the conductive portion 430, the elastic piece portion 440 and the supporting portion 450 are integrally connected to the main body 410. More particularly, the abutment portion 420, the conductive portion 430, the elastic piece portion 440, the elastic ring 411, the pre-press portion 413 and the supporting portion 450 are integrally connected to the main body 410, however, the disclosure is not limited thereto. The aforementioned electronic component for example, can be one of a Quad Flat Package (QFP), a Low Profile Quad Flat Package (LQFP), an Analog to Digital converter (ADC), and a digital analog Converter (DAC). However, the disclosure is not limited thereto.

Thus, through the construction of the embodiments above, the disclosure is able to improve the problem of voltage drop caused by the testing apparatus, thus, not only advance the test results of electronic components, but also maintain the service life of contacts of the circuit board of the testing apparatus.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A testing apparatus, comprising:
a circuit board comprising a board body, at least one via portion penetrated through the board body, and at least one electrical contact located on one surface of the board body and electrically connected to the at least one via portion;
at least one base located on the circuit board and formed with at least one limiting groove; and
at least one conductive terminal comprising:
a main body held within the at least one limiting groove;
an abutment portion extended outwardly from one side of the main body for contacting with a contact pin of a device under test (DUT);
a conductive portion extended outwardly from the side of the main body, and removably contacting with the at least one electrical contact;
an elastic piece portion connected to the conductive portion and the abutment portion; and
at least one supporting portion extended outwardly from another side of the main body, arranged opposite to the conductive portion, and removably contacting with the circuit board.

2. The testing apparatus of claim 1, wherein the circuit board further comprises:
at least one dummy contact located on the surface of the board body, electrically insulated from the at least one via portion and the at least one electrical contact, and one surface of the at least one dummy contact and one surface of the at least one electrical contact are at the same height,
wherein the conductive portion is in contact with the surface of the at least one electrical contact, and the at least one supporting portion is in contact with the surface of the at least one dummy contact.

3. The testing apparatus of claim 2, wherein the at least one electrical contact of the circuit board is closer to an orthographic projection of the DUT onto the board body than the at least one dummy contact.

4. The testing apparatus of claim 1, wherein the main body is recessed with a recess connected to the elastic piece portion, and the elastic piece portion protrudes toward the recess.

5. The testing apparatus of claim 1, wherein the elastic piece portion is C-shaped or V-shaped.

6. The testing apparatus of claim 1, wherein the abutment portion is provided with an arc-shaped outer edge, and the arc-shaped outer edge is used to be in contact with the contact pin.

7. The testing apparatus of claim 1, wherein the main body is further provided with an elastic ring, the elastic ring is formed with a through hole, located between the conductive portion and the at least one supporting portion, and collectively supported by the conductive portion and the at least one supporting portion in a suspended manner.

8. The testing apparatus of claim 1, wherein the main body is further provided with a pre-press portion that is opposite to the board body and between the abutment portion and the at least one supporting portion for abutting against the base so that the at least one conductive terminal is pressed to the circuit board.

9. The testing apparatus of claim 1, wherein the abutment portion, the conductive portion, the elastic piece portion and the at least one supporting portion are integrally connected to the main body.

10. The testing apparatus of claim 1, wherein the at least one supporting portion comprises two supporting portions, and the supporting portions and the conductive portion are arranged in a triangle together.

11. The testing apparatus of claim 2, wherein the at least one electrical contact comprises a plurality of electrical contacts spaced arranged on the surface of the board body so as to collectively outline a first rectangular contour;
the at least one dummy contact comprises a plurality of dummy contact spaced arranged on the surface of the board body so as to collectively outline a second rectangular contour surrounding the electrical contacts therein; and
the at least one base comprises four bases spaced arranged on the surface of the board body according to the first rectangular contour,
wherein the testing apparatus is used to test an electronic component which is one of a Quad Flat Package (QFP), a Low Profile Quad Flat Package (LQFP), an Analog to Digital converter (ADC), and a digital analog Converter (DAC).

12. A conductive terminal, comprising:
a main body;
an abutment portion extended outwardly from one side of the main body for contacting with a contact pin of a device under test (DUT);
a conductive portion extended outwardly from the side of the main body for contacting an electrical contact of a circuit board;
an elastic piece portion connected to the abutment portion and the conductive portion; and
at least one supporting portion extended outwardly from another side of the main body, arranged opposite to the conductive portion, and removably contacting with the circuit board.

13. The conductive terminal of claim 12, wherein the main body is recessed with a recess connected to the elastic piece portion, and the elastic piece portion protrudes toward the recess.

14. The conductive terminal of claim 12, wherein the elastic piece portion is C-shaped or V-shaped.

15. The conductive terminal of claim 12, wherein the abutment portion is provided with an arc-shaped outer edge, and the arc-shaped outer edge is used to be in contact with the contact pin.

16. The conductive terminal of claim 12, wherein the main body is further provided with an elastic ring, the elastic ring is formed with a through hole, located between the conductive portion and the at least one supporting portion, and collectively supported by the conductive portion and the at least one supporting portion in a suspended manner.

17. The conductive terminal of claim 12, wherein the main body is further provided with a pre-press portion that is located between the abutment portion and the at least one supporting portion.

18. The conductive terminal of claim 12, wherein the abutment portion, the conductive portion, the elastic piece portion and the at least one supporting portion are integrally connected to the main body.

19. The conductive terminal of claim 12, wherein the at least one supporting portion comprises two supporting portions, and the supporting portions and the conductive portion are arranged in a triangle together.
